(19) United States
(12) Patent Application Publication
(10) Pub. No.: US 2026/0283008 A1
(43) Pub. Date: Sep. 17, 2026

(54) MANUFACTURING METHOD OF ELECTRONIC DEVICE

(71) Applicants: Innolux Corporation, Miaoli County (TW); nD-HI Technologies Lab, Inc., Taipei City (TW)

(72) Inventors: Chun-Yu Chien, Miaoli County (TW); Chih-Chao Chuang, Miaoli County (TW); Ching-Yu Chu, Miaoli County (TW); Szu-Yen Yu, Miaoli County (TW); Ho-Ming Tong, Taipei City (TW)

(73) Assignees: Innolux Corporation, Miaoli County (TW); nD-HI Technologies Lab, Inc., Taipei City (TW)

(21) Appl. No.: 19/537,435

(22) Filed: Feb. 11, 2026

Related U.S. Application Data
(60) Provisional application No. 63/771,014, filed on Mar. 13, 2025.

(30) Foreign Application Priority Data
Nov. 3, 2025 (CN) 202511595089.5

(51) Int. Cl. H10W 74/10; H10W 90/00

(52) U.S. Cl. CPC H10W 74/142; H10W 74/117; H10W 90/722; H10W 90/754

(57) ABSTRACT

Provided is a manufacturing method of an electronic device, which includes the following. First package module includes at least one metal post and first encapsulant covering at least one metal post. Second package module is disposed in opening of first package module, and includes electronic component and second encapsulant covering the electronic component. Third encapsulant is formed to at least fill a gap between opening of the first package module and the second package module. A first circuit structure is formed on bottom surface of the first package module, and is at least electrically connected to the at least one metal post of the first package module. A second circuit structure is formed on a top surface of the first package module. The second circuit structure is electrically connected to the at least one metal post of the first package module and the electronic component of the second package module.

### CROSS-REFERENCE TO RELATED APPLICATION

This application claims the priority benefits of U.S. provisional application serial no. 63/771,014, filed on Mar. 13, 2025, and China application serial no. 202511595089.5, filed on Nov. 3, 2025. The entirety of each of the above-mentioned patent applications is hereby incorporated by reference herein and made a part of this specification.

### BACKGROUND

### Technical Field

The disclosure relates to a manufacturing method of an electronic device, and particularly relates to a manufacturing method of an electronic device having better structural reliability.

### Related Art

Electronic devices include packaging components applied to heterogeneous component integration or embedding different functional components. Since packaging components or substrates may include multiple materials, interface issues may appear during heterogeneous integration, or overall packaging deformation issues may result in poor yield during chip bonding.

### SUMMARY

The disclosure provides a manufacturing method of an electronic device, which may have better structural reliability.

In an embodiment of the disclosure, a manufacturing method of an electronic device includes the following steps. A first package module is provided. The first package module includes at least one metal post and a first encapsulant covering the at least one metal post, and the first package module has a top surface and a bottom surface opposite to each other and an opening penetrating through the first encapsulant. A second package module is disposed in an opening of the first package module. The second package module includes an electronic component and a second encapsulant covering the electronic component. A third encapsulant is formed to at least fill a gap between the opening of the first package module and the second package module. A first circuit structure is formed on a bottom surface of the first package module. The first circuit structure is at least electrically connected to the at least one metal post of the first package module. A second circuit structure is formed on a top surface of the first package module. The second circuit structure is electrically connected to the at least one metal post of the first package module and the electronic component of the second package module.

Based on the above, the first package module and the second package module are first provided separately, and then the second package module is disposed in the opening of the first package module, with the third encapsulant at least filling the gap between the opening of the first package module and the second package module. Therefore, through the above structural configuration, interface issues and packaging deformation issues that appear during subsequent heterogeneous integration may be reduced, the structural reliability of the overall electronic device may be increased, and the second package module disposed in the opening may improve the functionality of the electronic device.

To make the foregoing features and advantages of the disclosure more comprehensible, embodiments are specifically provided below and described in detail with reference to the accompanying drawings as follows.

### BRIEF DESCRIPTION OF THE DRAWINGS

FIGS. 1A TO 1D illustrate cross-sectional schematic diagrams of a manufacturing method of an electronic device according to an embodiment of the disclosure.

FIG. 2A shows a schematic top view of an electronic device according to an embodiment of the disclosure.

FIG. 2B is a schematic cross-sectional view along a line I-I in FIG. 2A.

FIG. 2C is an enlarged schematic diagram of a region A in FIG. 2B.

FIGS. 3 to 5 show schematic cross-sectional views of various electronic devices according to multiple embodiments of the disclosure.

### DESCRIPTION OF THE EMBODIMENTS

The disclosure may be understood by referring to the following detailed description in conjunction with the accompanying drawings. It should be noted that, for ease of understanding by readers and for simplicity of the drawings, multiple drawings in the disclosure merely show a portion of the electronic device, and specific elements in the drawings are not drawn to actual scale. Furthermore, the number and dimensions of each element in the drawings are merely illustrative and are not intended to limit the scope of the disclosure.

In some embodiments of the disclosure, terms regarding bonding and connection such as "connect," "interconnect," and the like, unless specifically defined, may refer to two structures being in direct contact, or may also refer to two structures not being in direct (indirect) contact, in which other structures are disposed between the two structures. Moreover, these terms regarding bonding and connection may also include cases where both structures are movable, or both structures are fixed. Furthermore, the term "couple" includes means of transmitting energy between two structures through direct or indirect electrical connection, or transmitting energy between two separate structures by means of mutual induction.

It should be understood that when a component or film layer is referred to as being "on" or "connected to" another element or film layer, it may be directly on or directly connected to the other element or film layer, or there may be intervening elements or film layers therebetween (indirect case). Conversely, when a component is referred to as being "directly" "on" or "directly connected to" another element or film layer, no intervening elements or film layers exist therebetween.

In the disclosure, the definition of roughness determination may be observed under appropriately same magnification to observe surface undulation conditions using, for example, SEM, transmission electron microscope (TEM), and by taking a unit length (for example, 10μm) sample for comparison on the uneven surface, the peaks and valleys of surface undulation have a distance difference of 0.15 micrometers (μm) to 1μm. Here, "appropriate magnification" means that at least one surface may see at least 10 undulating peaks under the field of view of this magnification with roughness (Rz) or average roughness (Ra).

The electronic device of the disclosure may include a power module, a semiconductor device, a semiconductor packaging device, a display device, an antenna device, a sensing device, a light-emitting device, or a tiled device, but the disclosure is not limited thereto. The electronic device may include a bendable or flexible electronic device. The electronic device may include electronic components. The electronic components may include passive components, active components, or combinations thereof, such as capacitors, resistors, inductors, variable capacitors, filters, diodes, transistors, sensors, microelectromechanical system components, liquid crystal chips, but the disclosure is not limited thereto. The diodes may include light-emitting diodes or non-light-emitting diodes. The following will use a display device as an electronic device to describe the content of the disclosure, but the disclosure is not limited thereto. According to embodiments of the disclosure, the provided manufacturing method of the electronic device may be applied to, for example, wafer level packaging (WLP) or panel level packaging (PLP) processes, and may adopt chip first processes or chip last/RDL first processes, which will be described in further detail below. The electronic device referred to in the disclosure may include system on chip (SoC), system in package (SiP), antenna in package (AiP), co-packaged optics (CPO), or combinations thereof, but the disclosure is not limited thereto.

Reference will now be made in detail to exemplary embodiments of the disclosure, examples of the exemplary embodiments are illustrated in the accompanying drawings. Wherever possible, the same reference numerals are used in the drawings and the description to refer to the same or like parts.

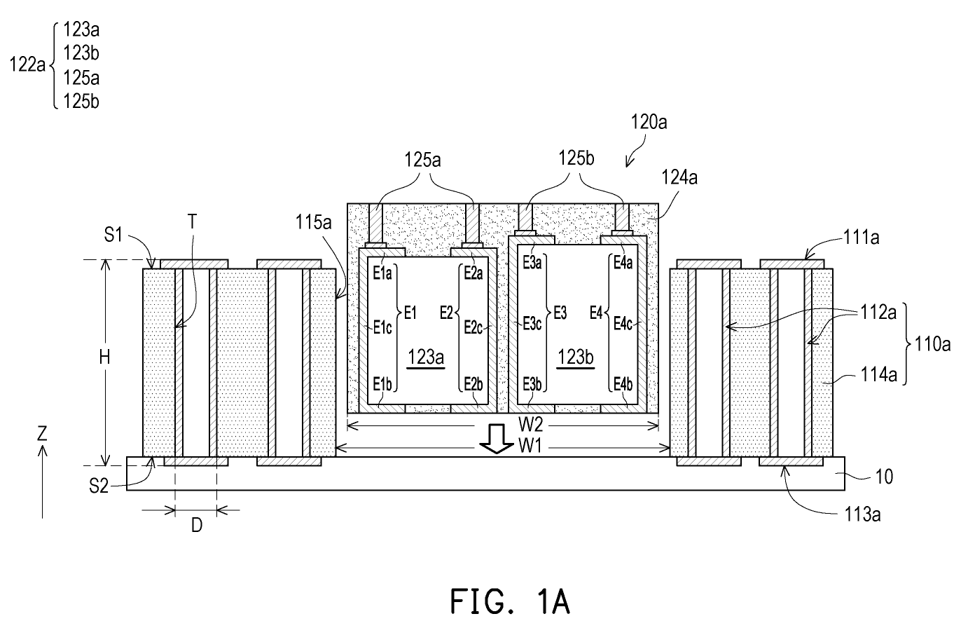

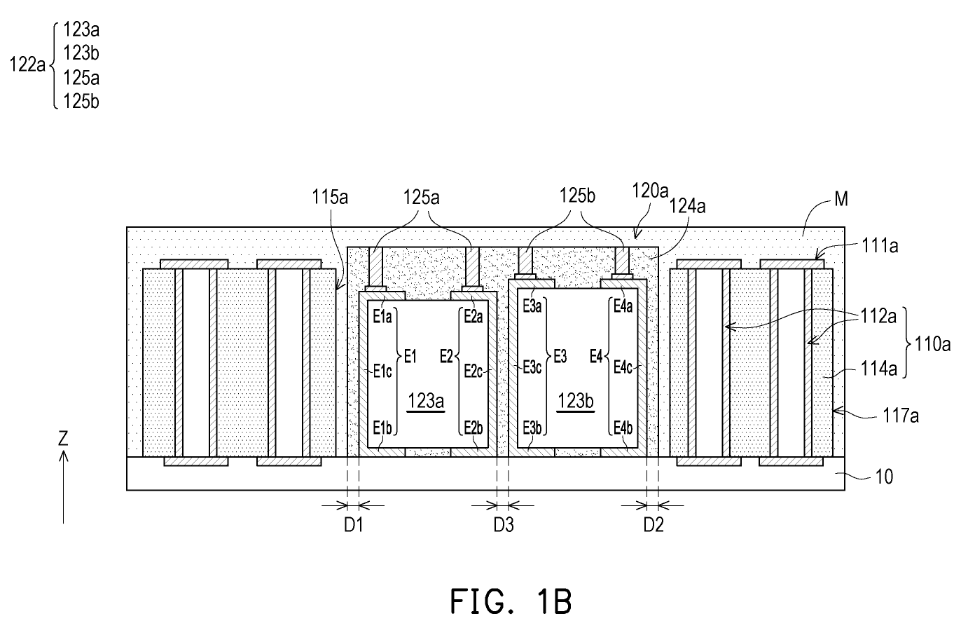

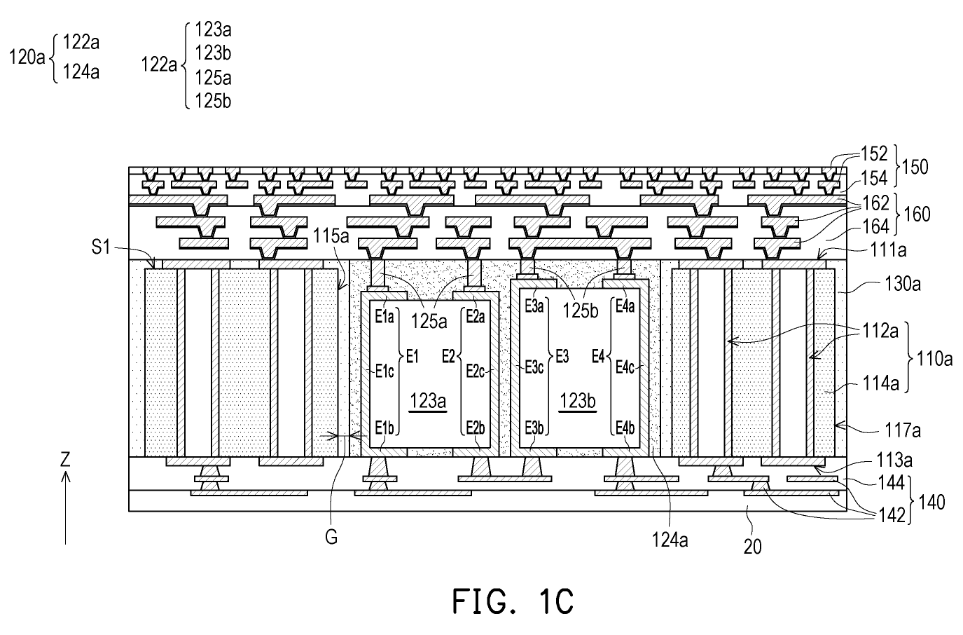

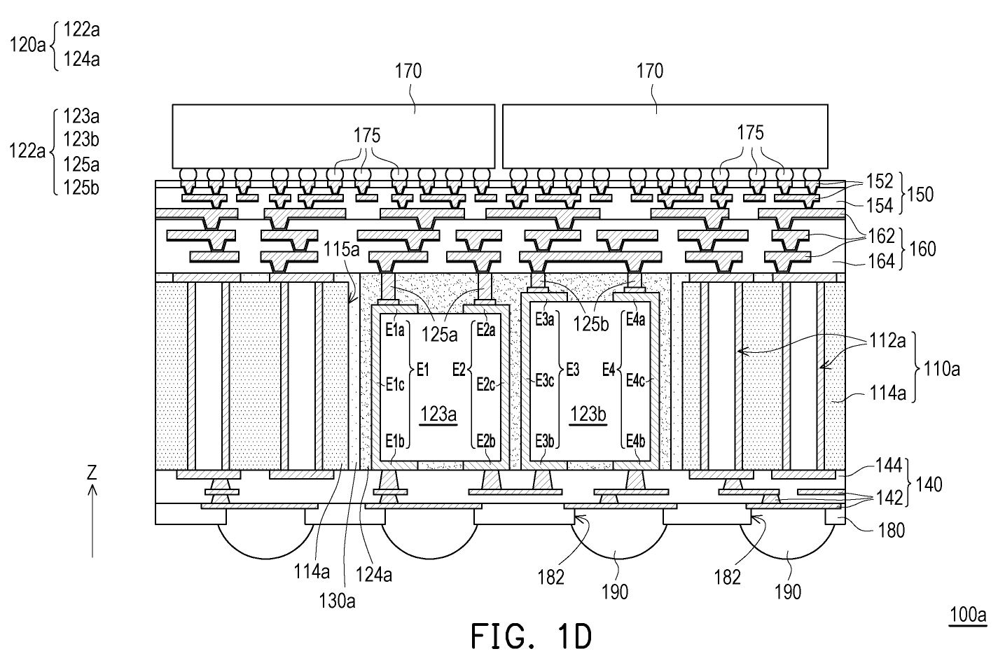

FIGS. 1A to 1D illustrate cross-sectional schematic diagrams of a manufacturing method of an electronic device according to an embodiment of the disclosure. Referring to FIG. 1A first, regarding the manufacturing method of the electronic device of the present embodiment, first, a first package module 110a is provided on a carrier having a release layer 10. The first package module 110a includes at least one metal post 112a and a first encapsulant 114a covering the at least one metal post 112a, or the first package module 110a includes a plurality of metal posts 112a separated from each other and a first encapsulant 114a covering the plurality of metal posts 112a, and the first package module 110a has a top surface 111a and a bottom surface 113a opposite to each other and an opening 115a penetrating through the first encapsulant 114a. In one embodiment, the first encapsulant 114a may be formed first, then, vias T are formed in the first encapsulant 114a through laser or mechanical drilling, in which the depth/width ratio of the vias T may be greater than or equal to 5 and less than or equal to 20. Then, metal layers may be formed in the vias T and on a top surface S1 and a bottom surface S2 opposite to each other of the first encapsulant 114a through transfer, pick-up, chemical plating, electroplating, other suitable methods, or combinations thereof. Then, the metal layers may be selectively patterned to form the metal posts 112a, but the disclosure is not limited thereto. Thereafter, the opening 115a penetrating through the first encapsulant 114a may be formed through laser drilling, cutting process, plasma process, or other appropriate processes, in which the opening 115a may have a width W1. In one embodiment, the top surface 111a and the bottom surface 113a of the first package module 110a are respectively two ends of the metal posts 112a opposite to each other. In one embodiment, the metal posts 112a may be hollow structures, in which the metal posts 112a may be selectively filled with materials, such as epoxy resin or heat dissipation materials, such as graphite or silver nanoparticles, but the disclosure is not limited thereto. In one embodiment, a height H of the metal posts 112a is, for example, 200 micrometers to 800 micrometers, and a diameter D of the metal posts 112a (such as the diameter in the vias T) is, for example, 80 micrometers to 400 micrometers. The bottom surface S2 of the first encapsulant 114a may directly contact the release layer 10, in which one end of the metal posts 112a (that is, the bottom surface 113a) is buried in the release layer 10, but the disclosure is not limited thereto. In one embodiment, the release layer 10 may include thermal release tape (HRT), light-to-heat-conversion (LTHC) release coating, or other suitable temporary adhesive materials.

Then, referring to FIGS. 1A and 1B simultaneously, a second package module 120a is disposed in the opening 115a of the first package module 110a. The second package module 120a includes an electronic component 122a and a second encapsulant 124a covering the electronic component 122a. The second package module 120a has a width W2 in a direction (that is, an X direction) perpendicular to a normal direction of the electronic device (that is, a Z direction), in which the width W2 is smaller than the width W1 of the opening 115a, which may avoid collision during configuration. In one embodiment, the electronic component 122a includes electronic units 123a, 123b and a plurality of connectors 125a, 125b configured on the electronic units 123a, 123b. The electronic unit 123a has a plurality of terminals E located on opposite sides, for example, two terminals E1, E2 have different polarities, the terminals E1, E2 respectively include upper terminal portions E1a, E2a, lower terminal portions E1b, E2b, and side terminal portions E1c, E2c connecting the upper terminal portions E1a, E2a with the lower terminal portions E1b, E2b, in which one connector 125a is respectively configured on the upper terminal portions E1a, E2a, and the lower terminal portions E1b, E2b are exposed by the second encapsulant 124a and may directly contact the release layer 10. The electronic unit 123b has two terminals E3, E4 located on opposite sides, the terminals E3, E4 respectively include upper terminal portions E3a, E4a, lower terminal portions E3b, E4b, and side terminal portions E3c, E3c connecting the upper terminal portions E3a, E4a with the lower terminal portions E3b, E4b, in which one connector 125b is respectively configured on the upper terminal portions E3a, E4a, and the lower terminal portions E3b, E4b are exposed by the second encapsulant 124a and may directly contact the release layer 10. In one embodiment, minimum distances D1, D2 are provided between the side terminal portions E1c, E4c of the electronic units 123a, 123b and an edge of the second encapsulant 124a, in which the minimum distances D1, D2 should be greater than or equal to 10 micrometers, which may avoid cutting damage to the terminals and affect electrical properties. In one embodiment, a minimum distance D3 is provided between the side terminal portions E2c, E3c of the electronic units 123a, 123b, in which the minimum distance D3 should be greater than or equal to 1.5 times the minimum width of one of the terminals, which may avoid the terminals from touching together and affecting electrical properties. In one embodiment, the electronic units 123a, 123b have different dimensions (such as height), in which the electronic units 123a, 123b may be, for example, active components, such as transistors, integrated circuits, or passive components, such as capacitors, inductors, but the disclosure is not limited thereto. In one embodiment, the connectors 125a, 125b are formed through, for example, a wire bonding process, in which after the second encapsulant 124a packages the electronic component 122a, a grinding process may be performed to grind portions of the second encapsulant 124a and portions of the connectors 125a, 125b, so that the electronic units 123a, 123b with different dimensions have flat bonding surfaces.

Then, referring to FIG. 1B again, a packaging material M is formed to cover the first package module 110a and the second package module 120a, in which the packaging material M covers the release layer 10 and the top surface 111a, a peripheral surface 117a of the first package module 110a and fills in the opening 115a.

Then, referring to FIGS. 1B and 1C simultaneously, the structure in FIG. 1B is flipped 180 degrees to another carrier having a release layer, exposing the bottom surface 113a of the first package module 110a and the lower terminal portions E1b, E2b, E3b, E4b of the electronic units 123a, 123b of the second package module 120a. Subsequently, a first circuit structure 140 is formed on the bottom surface 113a of the first package module 110a, in which the first circuit structure 140 is at least electrically connected with the metal post 112a of the first package module 110a. The first circuit structure 140 includes a metal layer 142 and a dielectric layer 144. In one embodiment, the metal layer 142 of the first circuit structure 140 is electrically connected with the metal post 112a of the first package module 110a and the lower terminal portions E1b, E2b, E3b, E4b of the electronic units 123a, 123b of the second package module 120a. In one embodiment, the material of the dielectric layer 144 is, for example, Photosensitive Polyimide (PSPI) or Ajinomoto build-up film (ABF) containing filler. In one embodiment, the first circuit structure 140 is, for example, a coarse pitch redistribution layer structure.

Then, referring to FIGS. 1B and 1C simultaneously again, the above structure is flipped 180 degrees to another carrier having a release layer 20. Subsequently, at least a portion of the packaging material M is removed to expose at least a portion of the surface of the metal post 112a of the first package module 110a flush with the electronic component 122a of the second package module 120, thereby forming a third encapsulant 130a that at least fills in the opening 115a of the first package module 110a and a gap G between the second package module 120a. At least a portion of the third encapsulant 130a is disposed on the top surface S1 of the first encapsulant 114a, in which the gap G should be greater than or equal to 10 micrometers to facilitate filling of the packaging material M. Here, through the above method, interface issues and packaging deformation issues that appear during subsequent heterogeneous integration may be reduced, and the structural reliability of the overall electronic device may be increased.

Then, referring to FIG. 1C, a second circuit structure 150 is formed on the top surface 111a of the first package module 110a, in which the second circuit structure 150 is electrically connected with the metal post 112a of the first package module 110a and the electronic component 122a of the second package module 120a. The second circuit structure 150 includes a metal layer 152 and a dielectric layer 154. In one embodiment, the material of the dielectric layer 154 is, for example, silicon dioxide (SiO₂), silicon nitride (SiN_{X}), photosensitive polyimide, or Ajinomoto build-up film containing filler. In one embodiment, the second circuit structure 150 is, for example, a fine pitch redistribution layer structure, that is, the thickness of the dielectric layer 154 of the second circuit structure 150, the thickness of the metal layer 152, or the distance between adjacent metal layers 152 are all smaller than the thickness of the dielectric layer 144 of the first circuit structure 140, the thickness of the metal layer 142, or the distance between adjacent metal layers 142.

In one embodiment, a third circuit structure 160 may also be included between the second circuit structure 150 and the first package module 110a, in which the third circuit structure 160 includes a metal layer 162 and a dielectric layer 164. The metal post 112a of the first package module 110a and the connectors 125a, 125b of the electronic component 122a of the second package module 120a are structurally and electrically connected with the metal layer 162 of the third circuit structure 160. In one embodiment, the metal layers 142, 152, 162 are, for example, traces, conductive vias, conductive blind holes, pads, or combinations thereof, as long as they have conductive function, they all belong to the metal layers 142, 152, 162 described in this disclosure. In one embodiment, the material of the metal layers 142, 152, 162 may be, for example, copper, titanium, nickel, or combinations or alloys of the above materials. In one embodiment, the material of the dielectric layer 164 is, for example, photosensitive polyimide or Ajinomoto build-up film containing filler. In one embodiment, the thickness of the dielectric layer 164 of the third circuit structure 160, the thickness of the metal layer 162, or the distance between adjacent metal layers 162 are all smaller than the thickness of the dielectric layer 144 of the first circuit structure 140, the thickness of the metal layer 142, or the distance between adjacent metal layers 142, and greater than the thickness of the dielectric layer 154 of the second circuit structure 150, the thickness of the metal layer 152, or the distance between adjacent metal layers 152.

It should be noted that the number of layers of the metal layers 142, 152, 162 may be the same or different, and may also be increased or decreased according to requirements. In one embodiment, the method for forming the redistribution structure layer may include using a dual damascene process, lithography etching process, surface treatment process, laser process, electroplating process, deposition process, combinations of the above processes, or other processes to form at least one dielectric layer and at least one metal layer stacked along the normal direction (the Z direction) of the electronic device, and the trace fan-out area may be adjusted. The surface treatment process includes roughening or activating the surface of the dielectric layer or the surface of the metal layer to enhance the adhesion capability thereof. For example, by enhancing the surface roughness to improve the bonding force with subsequent film layers.

Then, referring to FIGS. 1C and 1D simultaneously, an electronic component 170 is configured on the second circuit structure 150, in which the electronic component 170 is electrically connected to the metal layer 152 of the second circuit structure 150 through a connection element 175. In one embodiment, the electronic component 170 may be, for example, a known good die (KGD), a diode, an antenna unit, a sensor, a structure of semiconductor-related processes, or a suitable structure, but the disclosure is not limited thereto. In one embodiment, the material of the connection element 175 may be, for example, copper, nickel, tin, silver, gold, gallium, or combinations thereof, but the disclosure is not limited thereto. In one embodiment, the pad of the electronic component 170 may also be electrically connected to the metal layer 152 of the second circuit structure 150 through hybrid bonding. In one embodiment, a filling layer may also be formed between each electronic component 170 and the second circuit structure 150, in which the filling layer may be, for example, an organic material or an inorganic material, may directly contact the active surface of the electronic component 170 and the top surface of the second circuit structure 150, and fill the space between two adjacent connection elements 175 for protecting the connection elements 175 or ensuring the bonding between the electronic component 170 and the second circuit structure 150.

Then, referring to FIGS. 1C and 1D simultaneously, the release layer 20 is removed to expose the outermost metal layer 142 of the first circuit structure 140. A solder mask layer 180 may be formed on the first circuit structure 140, in which the solder mask layer 180 has an opening 182 exposing a portion of the metal layer 142. Finally, a solder ball 190 is formed in the opening 182 of the solder mask layer 180 and is electrically connected to the metal layer 142. The manufacturing of an electronic device 100a may be completed with a dicing step.

In the embodiment of the disclosure, the first package module 110a and the second package module 120a are provided separately first, and then the second package module 120a is disposed in the opening 115a of the first package module 110a, with the third encapsulant 130a at least filling the gap G between the opening 115a of the first package module 110a and the second package module 120a. Therefore, through the above structural configuration, interface issues and package deformation issues that appear during subsequent heterogeneous integration may be reduced, the structural reliability of the overall electronic device 100a may be increased, and the configuration of the second package module 120a may improve the functionality of the electronic device 100a.

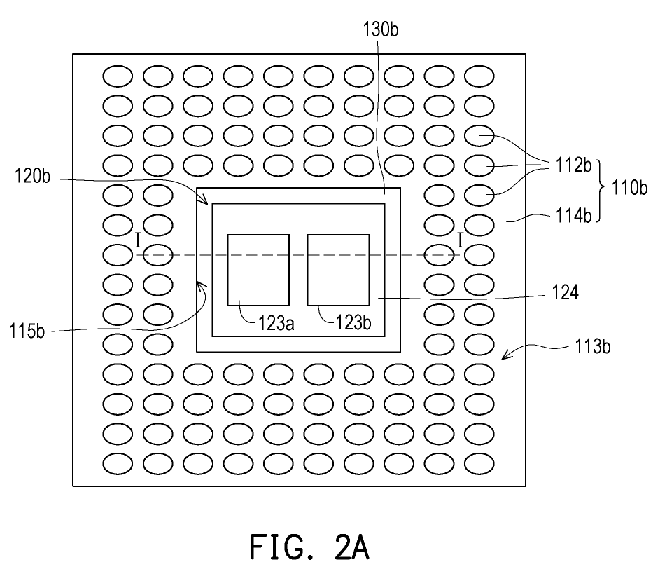

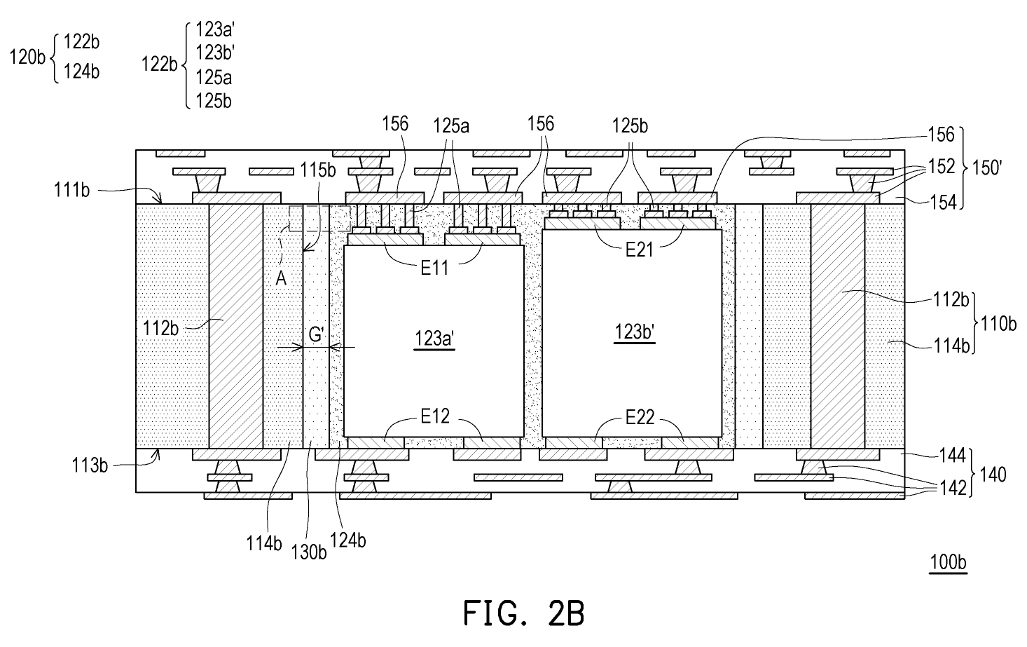

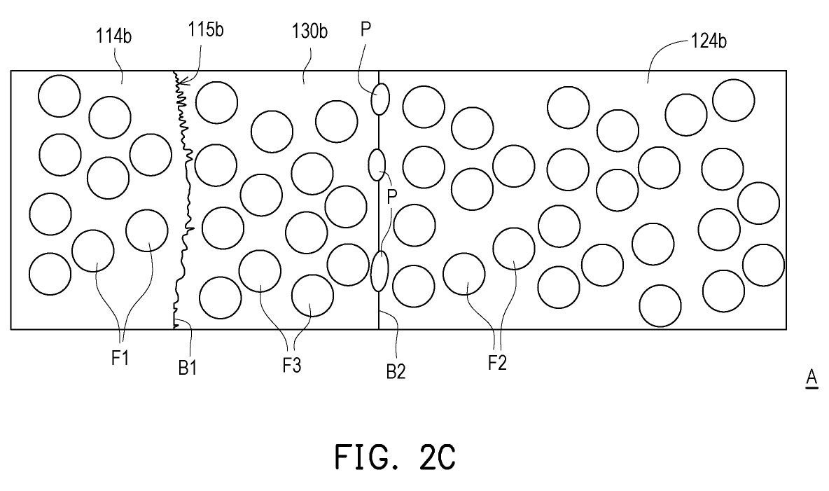

FIG. 2A shows a schematic top view of an electronic device according to an embodiment of the disclosure. FIG. 2B is a schematic cross-sectional view along a line I-I in FIG. 2A. FIG. 2C is an enlarged schematic diagram of a region A in FIG. 2B. For convenience of description, the first circuit structure and the second circuit structure are omitted in FIG. 2A. Referring to FIGS. 1D, 2A, and 2B, simultaneously, an electronic device 100b of this embodiment is similar to the electronic device 100a in FIG. 1D, and the difference between the two devices is that, in this embodiment, the metal posts 112b of the first package module 110b may be solid metal posts. In one embodiment, the metal posts 112b may be first dispersedly disposed on a release layer, then a first encapsulant 114b is formed on the release layer to completely cover the metal posts 112b, after that, a grinding process may be selectively performed to remove portions of the first encapsulant 114b to expose one end of the metal posts 112b, and finally, an opening 115b penetrating through the first encapsulant 114b is formed through laser drilling, cutting process, plasma process, or other appropriate processes to complete the manufacturing of the first package module 110b. According to some embodiments, the first package module 110b may include multiple openings 115b. Here, the top surface 111b and the bottom surface 113b of the first package module 110b are respectively two opposite side surfaces of the first encapsulant 114b, in which the two opposite ends of the metal posts 112b are flush with the top surface 111b and the bottom surface 113b.

Furthermore, the second package module 120b of this embodiment is disposed in the opening 115b of the first package module 110b, and two opposite sides of the second encapsulant 124b of the second package module 120b are flush with the top surface 111b and the bottom surface 113b of the first package module 110b. The electronic component 122b of the second package module 120b includes electronic units 123a', 123b' and multiple connectors 125a, 125b configured on the electronic units 123a', 123b'. For example, three connectors 125a, 125b are configured on each terminal E11, E21 of the electronic units 123a', 123b', and the terminals E12, E22 directly contact and electrically connect to the metal layer 142 of the first circuit structure 140.

Furthermore, the second circuit structure 150' of this embodiment is directly formed on the top surface 111b of the first package module 110b, in which the second circuit structure 150' includes a metal layer 152, a dielectric layer 154, and pads 156. The metal layer 152 electrically connects to the metal posts 112b of the first package module 110b, and the electronic component 122b of the second package module 120b electrically connects to the pads 156 of the second circuit structure 150' through the connectors 125a, 125b.

Referring to FIGS. 2B and 2C simultaneously, there is a first interface B1 between the first encapsulant 114b and the third encapsulant 130b, and a second interface B2 between the second encapsulant 124b and the third encapsulant 130b. In a cross-sectional view, the first interface B1 and the second interface B2 have non-flat interfaces, such as wavy interfaces or uneven interfaces. A gap G' includes at least one void P formed on at least one of the first interface B1 and the second interface B2, in which the number of voids P should be less than or equal to 10. That is, the voids P may be formed on the first interface B1, or formed on the second interface B2, or formed on both the first interface B1 and the second interface B2. In one embodiment, the voids P are, for example, air gaps, in which since the first encapsulant 114b, the second encapsulant 124b, and the third encapsulant 130b are not formed simultaneously, gaps may appear between the interfaces of the package bodies. In one embodiment, the dimension of the voids P is, for example, less than or equal to 50 micrometers, 20 micrometers, or 10 micrometers to enhance reliability.

In one embodiment, the material of the first encapsulant 114b, the material of the second encapsulant 124b, and the material of the third encapsulant 130b are the same. In one embodiment, the material of the first encapsulant 114b, the material of the second encapsulant 124b, and the material of the third encapsulant 130b are different. In one embodiment, the material of the first encapsulant 114b, the material of the second encapsulant 124b, and the material of the third encapsulant 130b are respectively polymers having fillers F1, F2, F3 of the same dimension. In one embodiment, the material of the first encapsulant 114b and the material of the second encapsulant 124b are respectively polymers having fillers with a first dimension, and the material of the third encapsulant 130b is a polymer having fillers with a second dimension, in which the second dimension is smaller than the first dimension. In one embodiment, the first dimension of the fillers in the first encapsulant 114b and the second encapsulant 124b is, for example, 5 micrometers to 60 micrometers, the percentage of the fillers is, for example, 80wt% to 90wt%, and the viscosity of the first encapsulant 114b and the second encapsulant 124b is 50cP to 2000cP; the second dimension of the fillers in the third encapsulant 130b is, for example, 0.1 micrometers to 30 micrometers, and the percentage of the fillers is, for example, 40 wt% to 85wt%, and the viscosity of the third encapsulant 130b is 30cP to 1500cP. In one embodiment, the material of the first encapsulant 114b and the material of the second encapsulant 124b are respectively polymers having fillers with the same dimension, and the material of the third encapsulant 130b is a polymer without fillers. The material of the first encapsulant 114b and the material of the second encapsulant 124b are respectively polymers having fillers with different dimensions, and the material of the third encapsulant 130b is a polymer without fillers. In one embodiment, the material of the first encapsulant 114b, the material of the second encapsulant 124b, and the material of the third encapsulant 130b are respectively polymers without fillers, in which the viscosity of the third encapsulant 130b is 50 cP to 1500 cP, or 10000 cP to 50000 cP, and the capillary flow of the third encapsulant 130b is 5mm/s to 50mm/s. The polymers mentioned above may be, for example, silicon dioxide, boron nitride, or aluminum oxide, but the disclosure is not limited thereto.

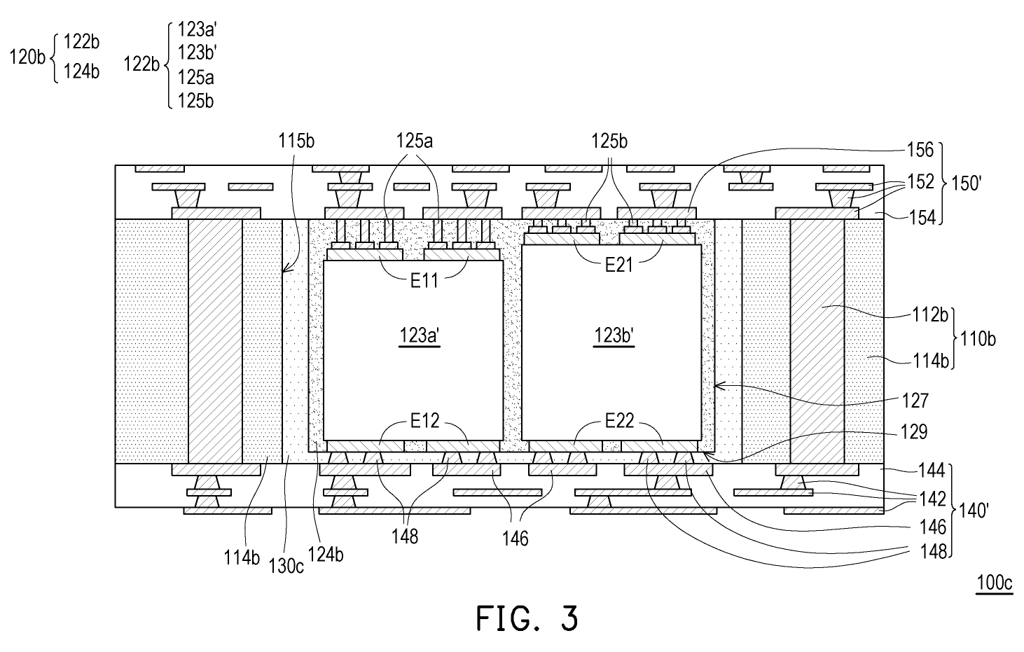

FIG. 3 shows a schematic cross-sectional view of an electronic device according to an embodiment of the disclosure. Referring to FIG. 2B and FIG. 3 simultaneously, an electronic device 100c of this embodiment is similar to the electronic device 100b in FIG. 2B, and the difference between the two devices is that, in this embodiment, a first circuit structure 140' further includes pads 146 and conductive blind vias 148, in which the conductive blind vias 148 pass through the third encapsulant 130c and are structurally and electrically connected to the terminals E12, E22 of the electronic units 123a', 123b', and the pads 146 are structurally and electrically connected to the conductive blind vias 148 corresponding to each terminal E12, E22. In one embodiment, the conductive blind vias 148 are formed through, for example, laser drilling and electroplating processes. The third encapsulant 130c fills in the opening 115b of the first package module 110b, and further covers a peripheral surface 127, a bottom surface 129 of the second encapsulant 124b of the second package module 120b and the conductive blind vias 148 of the first circuit structure 140'.

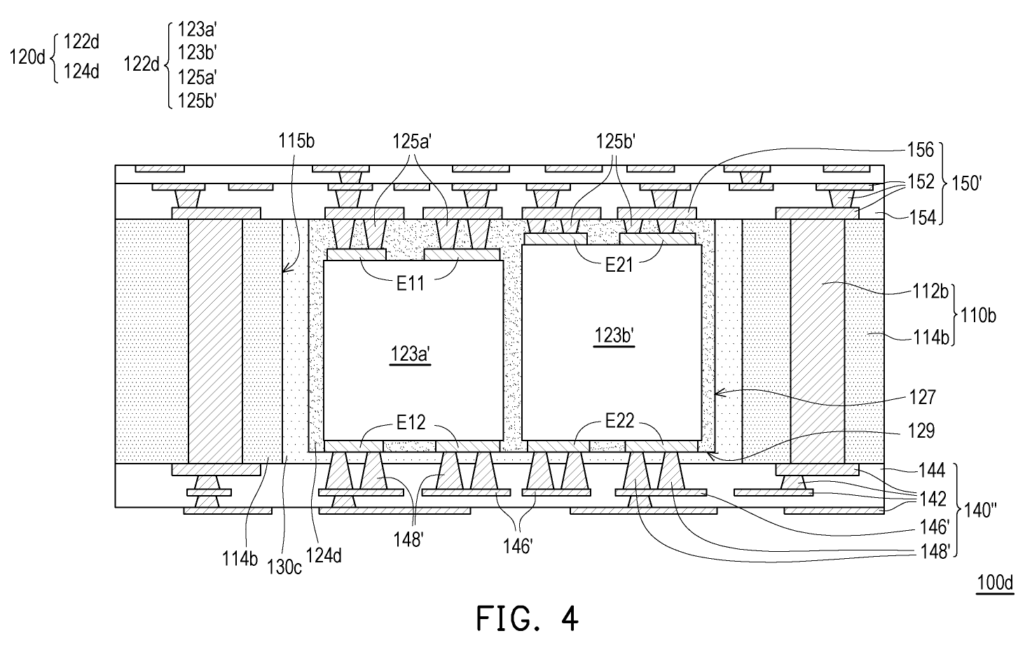

FIG. 4 shows a schematic cross-sectional view of an electronic device according to an embodiment of the disclosure. Referring to FIG. 3 and FIG. 4 simultaneously, an electronic device 100d of this embodiment is similar to the electronic device 100c in FIG. 3, and the difference between the two devices is that, in this embodiment, the electronic component 122d of the second package module 120d includes electronic units 123a', 123b' and a plurality of connectors 125a', 125b' configured on the electronic units 123a', 123b', in which the connectors 125a', 125b' are formed through, for example, laser drilling and electroplating processes. The pads 156 of the second circuit structure 150' may correspondingly connect to the connectors 125a', 125b' on each terminal E11, E21 of the electronic units 123a', 123b'. The conductive blind vias 148' of the first circuit structure 140'' pass through a portion of the dielectric layer 144 and a portion of the third encapsulant 130c and are structurally and electrically connected to each terminal E12, E22 of the electronic units 123a', 123b'. The pads 146' are structurally and electrically connected to the conductive blind vias 148' corresponding to each terminal E12, E22. Here, the number of conductive blind vias 148' corresponding to each terminal E12, E22 is not limited, as long as electrical connection may be maintained.

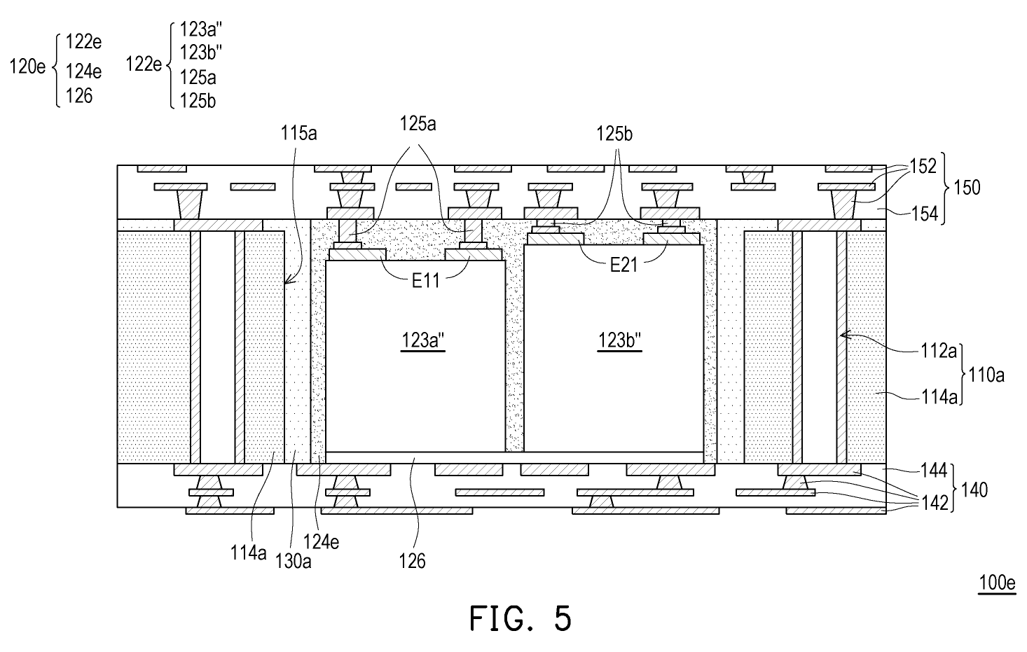

FIG. 5 shows a schematic cross-sectional view of an electronic device according to an embodiment of the disclosure. Referring to FIG. 1D and FIG. 5 simultaneously, an electronic device 100e of this embodiment is similar to the electronic device 100a in FIG. 1D, and the difference between the two devices is that, in this embodiment, the second package module 120e includes an electronic component 122e, a second encapsulant 124e covering the electronic component 122e, and an adhesive layer 126. The electronic component 122e includes electronic units 123a'', 123b'' and a plurality of connectors 125a, 125b configured on the electronic units 123a'', 123b''. One side surface of the electronic units 123a'', 123b'' has a plurality of terminals E11, E21, in which connectors 125a, 125b are configured on each terminal E11, E21, and an adhesive layer 126 is disposed on another side surface of the electronic units 123a'', 123b'', in which the adhesive layer 126 is flush with the second encapsulant 124e and directly contacts the first circuit structure 140.

In the embodiments of the disclosure, the first package module and the second package module are first provided separately, and then the second package module is disposed in the opening of the first package module, with the third encapsulant at least filling the gap between the opening of the first package module and the second package module. Through the above structural configuration, interface issues and package deformation issues that appear during subsequent heterogeneous integration may be reduced, the structural reliability of the overall electronic device may be increased, and the second package module disposed in the opening may improve the functionality of the electronic device.

Although the disclosure has been disclosed above with embodiments, the embodiments are not used to limit the disclosure. Persons having ordinary knowledge in the technical field may make slight changes and modifications without departing from the spirit and scope of the disclosure. Therefore, the protection scope of the disclosure shall be determined by the appended claims.

What is claimed is:

1. A manufacturing method of an electronic device, comprising:
providing a first package module, wherein the first package module comprises at least one metal post and a first encapsulant covering the at least one metal post, and the first package module has a top surface and a bottom surface opposite to each other and an opening penetrating through the first encapsulant;
disposing a second package module in the opening of the first package module, wherein the second package module comprises an electronic component and a second encapsulant covering the electronic component;
forming a third encapsulant to at least fill a gap between the opening of the first package module and the second package module;
forming a first circuit structure on the bottom surface of the first package module, wherein the first circuit structure is at least electrically connected to the at least one metal post of the first package module; and
forming a second circuit structure on the top surface of the first package module, wherein the second circuit structure is electrically connected to the at least one metal post of the first package module and the electronic component of the second package module.

2. The manufacturing method of the electronic device as claimed in claim 1, wherein a step of forming the third encapsulant comprises:
forming a packaging material to cover the first package module and the second package module, wherein the packaging material covers the top surface and a peripheral surface of the first package module and fills in the opening; and
after forming the first circuit structure, removing at least a portion of the packaging material to expose at least one metal post flush with the electronic component of the second package module, thereby forming the third encapsulant.

3. The manufacturing method of the electronic device as claimed in claim 2, wherein at least a portion of the third encapsulant is disposed on a top surface of the first encapsulant.

4. The manufacturing method of the electronic device as claimed in claim 1, wherein the electronic component of the second package module comprises an electronic unit and a plurality of connectors configured on the electronic unit, and the electronic unit is electrically connected to the second circuit structure through the connectors.

5. The manufacturing method of the electronic device as claimed in claim 4, wherein the electronic unit has a plurality of terminals, each of the terminals is respectively configured on one of the connectors, the second circuit structure comprises a plurality of pads, and each of the pads connects the connectors on each of the terminals.

6. The manufacturing method of the electronic device as claimed in claim 4, wherein the electronic unit has two terminals of different polarities, each of the terminals comprises an upper terminal portion, a lower terminal portion, and a side terminal portion connecting the upper terminal portion and the lower terminal portion, and a minimum distance of greater than or equal to 10 micrometers is provided between the side terminal portion and an edge of the second encapsulant.

7. The manufacturing method of the electronic device as claimed in claim 1, wherein the first circuit structure is further electrically connected to the electronic component of the second package module.

8. The manufacturing method of the electronic device as claimed in claim 1, wherein there is a first interface between the first encapsulant and the third encapsulant, a second interface between the second encapsulant and the third encapsulant, and at least one void is formed on at least one of the first interface and the second interface.

9. The manufacturing method of the electronic device as claimed in claim 8, wherein a dimension of the at least one void is less than or equal to 50 micrometers.

10. The manufacturing method of the electronic device as claimed in claim 8, wherein a dimension of the at least one void is less than or equal to 20 micrometers.

11. The manufacturing method of the electronic device as claimed in claim 8, wherein a dimension of the at least one void is less than or equal to 10 micrometers.

12. The manufacturing method of the electronic device as claimed in claim 8, wherein the first interface comprises a non-flat interface.

13. The manufacturing method of the electronic device as claimed in claim 1, wherein a material of the first encapsulant, a material of the second encapsulant, and a material of the third encapsulant are same.

14. The manufacturing method of the electronic device as claimed in claim 1, wherein a material of the first encapsulant, a material of the second encapsulant, and a material of the third encapsulant are different.

15. The manufacturing method of the electronic device as claimed in claim 1, wherein the at least one metal post comprises at least one hollow metal post or at least one solid metal post.

16. The manufacturing method of the electronic device as claimed in claim 1, wherein the at least one metal post comprises at least one via and a metal layer formed on an inner wall of the at least one via.

17. The manufacturing method of the electronic device as claimed in claim 1, wherein a height of the at least one metal post is 200 micrometers to 800 micrometers, and a diameter of the at least one metal post is 80 micrometers to 400 micrometers.

18. The manufacturing method of the electronic device as claimed in claim 1, wherein the gap is greater than or equal to 10 micrometers.

19. The manufacturing method of the electronic device as claimed in claim 1, further comprising:
forming a solder mask layer on the first circuit structure, wherein the solder mask layer has at least one opening exposing a portion of a metal layer of the first circuit structure; and
forming at least one solder ball in the at least one opening of the solder mask layer and electrically connected to the metal layer.

20. The manufacturing method of the electronic device as claimed in claim 1, wherein a material of the first encapsulant, a material of the second encapsulant, and a material of the third encapsulant respectively comprise polymers having fillers of same dimension.
